(19) United States
(12) Patent Application Publication
(10) Pub. No.: US 2024/0088002 A1
(43) Pub. Date: Mar. 14, 2024

(54) SYSTEM-LEVEL FAN-OUT PACKAGING STRUCTURE AND METHOD FOR MANUFACTURING SAME

(71) Applicant: SJ Semiconductor(Jiangyin) Corporation, Jiangyin City (CN)

(72) Inventors: Yenheng CHEN, Jiangyin City (CN); Chengchung LIN, Jiangyin City (CN)

(73) Assignee: SJ Semiconductor(Jiangyin) Corporation, Jiangyin City, JS (CN)

(21) Appl. No.: 18/244,315

(22) Filed: Sep. 11, 2023

(30) Foreign Application Priority Data
Sep. 13, 2022 (CN) 202211111839.3

(51) Int. Cl. H01L 23/498; H01L 21/48; H01L 21/56; H01L 21/683; H01L 23/00; H01L 23/29; H01L 25/065

(52) U.S. Cl. CPC H01L 23/49822; H01L 21/4853; H01L 21/4857; H01L 21/568; H01L 21/6835; H01L 23/293; H01L 23/49811; H01L 23/49838; H01L 23/49894; H01L 24/03; H01L 24/08; H01L 24/80; H01L 25/0655; H01L 2221/68359; H01L 2221/68372; H01L 2221/68381; H01L 2224/03916; H01L 2224/08225; H01L 2224/80895; H01L 2224/80896; H01L 2924/15174; H01L 2924/3511; H01L 2924/3512; H01L 2924/381

(57) ABSTRACT

A system-level fan-out packaging structure and a method for manufacturing the same are disclosed. The method includes: forming a rewiring layer on a supporting substrate, the rewiring layer having a first surface and a second surface opposite to the first surface, wherein the rewiring layer includes at least one inorganic dielectric layer and at least one metal wiring layer; forming a hybrid bonding structure between the first surface of the rewiring layer and semiconductor chips to electrically couple them, wherein the hybrid bonding structure includes a first bonding layer formed on the first surface of the rewiring layer; a plastic packaging layer on the first surface of the rewiring layer to cover the semiconductor chips; removing the supporting substrate to expose the second surface of the rewiring layer; and providing a packaging substrate electrically coupled to the second surface of the rewiring layer.

### CROSS REFERENCE TO RELATED APPLICATION

The present application claims the benefit of priority to Chinese Patent Application No. CN 202211111839.3, entitled “SYSTEM-LEVEL FAN-OUT PACKAGING STRUCTURE AND METHOD FOR MANUFACTURING SAME”, filed with CNIPA on Sep. 13, 2022, the disclosure of which is incorporated herein by reference in its entirety for all purposes.

### FIELD OF THE INVENTION

The present disclosure generally relates to semiconductor chip packaging, and in particular to a system-level fan-out packaging structure and a method for manufacturing the same.

### BACKGROUND OF THE INVENTION

As mobile consumer electronics, such as phones, personal digital assistants (PDAs), and digital cameras, demand higher levels of integration, larger storage space, miniaturization, and reliability in packaging, integrating multiple high-density chips into one powerful yet compact system or subsystem has become a major challenge in advanced semiconductor chip packaging.

System In Package (SIP) technology is an emerging heterogeneous integration technology that can integrate multiple active and passive devices, micro-electromechanical systems (MEMS), and/or optical components into a single package to form a system or subsystem with multiple functions. These have made SIP an increasingly popular packaging option for many systems. Currently, chips with different performance levels are first prepared using front end of line (FEOL) processes and are then attached to a through-silicon-via (TSV) interposer. The ultra-fine pins of the chips are then interconnected through the TSV interposer to form a functional module or system. However, this technology can be expensive, limiting its range of applications.

Additionally, as the demand for packaging components and functionality increases, existing system-level packaging structures may occupy larger areas and volumes than practical, hindering further integration.

### SUMMARY

The present disclosure provides a method for manufacturing a system-level fan-out packaging structure, including: forming a rewiring layer on a supporting substrate, the rewiring layer having a first surface and a second surface opposite to the first surface, wherein the rewiring layer includes at least one inorganic dielectric layer and at least one metal wiring layer; forming a hybrid bonding structure between the first surface of the rewiring layer and semiconductor chips to electrically couple the semiconductor chips to the first surface of the rewiring layer, wherein the hybrid bonding structure includes a first bonding layer formed on the first surface of the rewiring layer; forming a plastic layer on the first surface of the rewiring layer to form a packaging layer covering the semiconductor chips; removing the supporting substrate to expose the second surface of the rewiring layer; and providing a packaging substrate electrically coupled to the second surface of the rewiring layer, including forming a conductive interconnection between the second surface of the rewiring layer and the packaging substrate.

The present disclosure also provides a system-level fan-out packaging structure, including: a rewiring layer having a first surface and a second surface opposite to the first surface, wherein a first bonding layer is provided on the first surface of the rewiring layer, and the rewiring layer includes at least one inorganic dielectric layer and at least one metal wiring layer vertically stacked; a hybrid bonding structure, disposed on the first surface of the rewiring layer and electrically coupling semiconductor chips to the first surface of the rewiring layer for interconnection between the semiconductor chips through the rewiring layer, wherein the semiconductor chips are covered by a first plastic layer to form a packaging layer; and a packaging substrate, wherein a conductive interconnection is formed between the packaging substrate and the second surface of the rewiring layer, achieving electrical lead-out of the semiconductor chips and the rewiring layer.

The system-level fan-out type packaging structure of the present disclosure and the method for manufacturing the same have the following beneficial effects:
In the system-level fan-out packaging structure of the present disclosure, the hybrid bonding structure is used to bond the rewiring layer to the semiconductor chips without solder, avoiding cracks in the solder at the interface between the two and improving the reliability of interconnection, while increasing the functional integration of the fan-out packaging structure, providing more flexible chip heterogeneous integration solutions, and realizing a high-performance system-level fan-out packaging structure;
In the system-level fan-out packaging structure of the present disclosure, interconnections with line spacing less than 10 microns are achieved without using a TSV interposer, enabling heterogeneous integration and interconnection of multiple chips, reducing packaging manufacturing costs and reducing pin pitch, which can increase the density of I/O ports;
In the method for manufacturing the system-level fan-out packaging structure of the present disclosure, by using inorganic dielectric materials for insulating the rewiring layer, the line spacing within the rewiring layer is reduced to less than 1 μm, and hybrid bonding is achieved at the interface between the rewiring layer and the semiconductor chips. This avoids forming interfaces between organic and inorganic materials, improves process integration in packaging manufacturing, and minimizes package volume.

### BRIEF DESCRIPTION OF THE DRAWINGS

FIG. 1 shows a flowchart illustrating a method for manufacturing a system-level fan-out packaging structure of the present disclosure.

FIG. 2 shows a schematic diagram of an intermediate structure obtained after forming an inorganic dielectric layer on a supporting substrate according to one embodiment of the present disclosure.

FIG. 3 shows a schematic diagram of an intermediate structure obtained after forming a metal wiring layer according to one embodiment of the present disclosure.

FIG. 4 shows a schematic diagram of an intermediate structure obtained after forming a rewiring layer on the supporting substrate according to one embodiment of the present disclosure.

FIG. 5A shows a schematic diagram of an intermediate structure obtained after forming a first bonding layer on a first surface of the rewiring layer according to one embodiment of the present disclosure.

FIG. 5B shows a schematic diagram of an intermediate structure obtained after forming a second bonding layer on surfaces of semiconductor chips according to one embodiment of the present disclosure.

FIG. 6 shows a schematic diagram of an intermediate structure obtained after forming a hybrid bonding structure between the first surface of the rewiring layer and the semiconductor chips according to one embodiment of the present disclosure.

FIG. 7 shows a schematic diagram of an intermediate structure obtained after forming a first plastic layer over the first surface of the rewiring layer according to one embodiment of the present disclosure.

FIG. 8 shows a schematic diagram of an intermediate structure obtained after thinning the first plastic layer according to one embodiment of the present disclosure.

FIG. 9 shows a schematic diagram of an intermediate structure obtained after removing the supporting substrate according to one embodiment of the present disclosure.

FIG. 10 shows a schematic diagram of an intermediate structure obtained after forming a controlled collapse chip connection layer on a second surface of the rewiring layer according to one embodiment of the present disclosure.

FIG. 11 shows a schematic diagram of an intermediate structure obtained after forming a conductive interconnection layer between a packaging substrate and the second surface of the rewiring layer according to one embodiment of the present disclosure.

### DETAILED DESCRIPTION

The embodiments of the present disclosure will be described below. Those skilled can easily understand disclosure advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

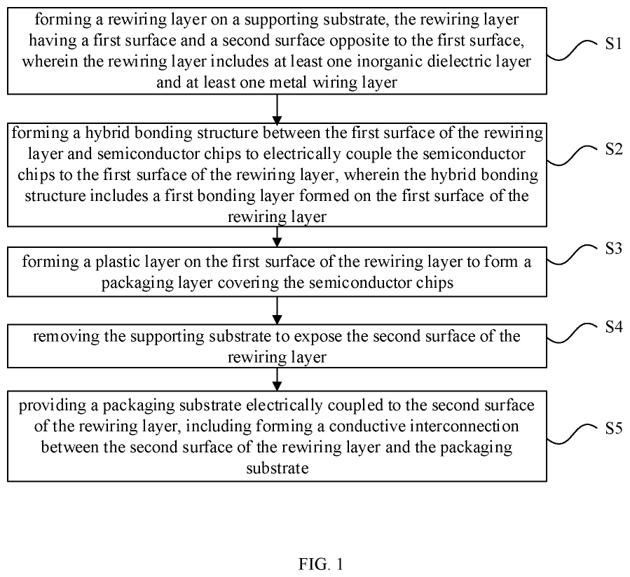

Refer to FIGS. 1-6. It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

The present disclosure provides a method for manufacturing a system-level fan-out packaging structure. FIG. 1 is a flowchart of the method, and the method includes the following steps:
S1: providing a supporting substrate, forming a rewiring layer on the supporting substrate, wherein the rewiring layer includes at least one inorganic dielectric layer and at least one metal wiring layer;
S2: forming a hybrid bonding structure between a first surface of the rewiring layer and semiconductor chips to electrically couple the semiconductor chips to the first surface of the rewiring layer;
S3: forming a plastic layer on the first surface of the rewiring layer to form a packaging layer covering the semiconductor chips;
S4: removing the supporting substrate to expose a second surface of the rewiring layer; and
S5: providing a packaging substrate electrically coupled to the second surface of the rewiring layer, including forming a conductive interconnection between the second surface of the rewiring layer and the packaging substrate.

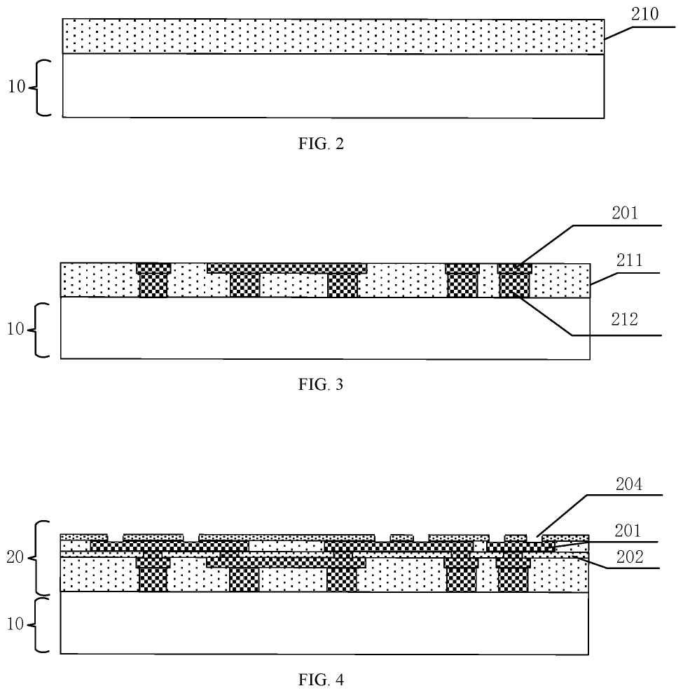

First, as shown in FIGS. 2 to 4, step S1 is performed by forming the rewiring layer 20 on the supporting substrate 10. Specifically, the supporting substrate 10 is used to prevent layered packaging structures formed upon it from cracking, warping, fracturing, etc. during the packaging process, and the supporting substrate 10 may a wafer, a panel, or of any other desired shape, and it can be made of materials such as silicon, glass, metal, semiconductor, polymer, and ceramics.

Referring to FIG. 2, step S1 includes: step S1-1, after forming a second inorganic dielectric layer 210 on the supporting substrate 10, and forming a plurality of vias (not shown) in the second inorganic dielectric layer 210 by laser etching or another drilling/etching process to obtain a patterned second inorganic dielectric layer 211.

Referring to FIG. 3, step S1 further includes: step S1-2, forming a metal wiring layer 201 in the patterned second inorganic dielectric layer 211.

Specifically, at steps S1-2, the metal wiring layer may include more than one patterning processes: first filling via holes located in the second inorganic dielectric layer with a metal material and then connecting the metal filled holes with contact pads above. The contact pads 212 are formed by first depositing a layer of metal material on the patterned second inorganic dielectric layer 211 by using sputtering, electroplating, chemical plating or other suitable processes, followed by a metal pattering process to obtain a metal wiring layer 201. The metal wiring layer 201 is made of one or more of copper, aluminum, nickel, gold, silver, and titanium.

Referring to FIG. 4, step S1 further includes: S1-3, forming a first patterned inorganic dielectric layer 202 over the metal wiring layer 201.

Specifically, steps S1-3 includes: forming a first inorganic dielectric layer over the metal wiring layer 201 using chemical vapor deposition, physical vapor deposition, or other suitable process, and patterning the first inorganic dielectric layer to form the first patterned inorganic dielectric layer 202. Some thinning of the first inorganic dielectric layer may be necessary for patterning. The first inorganic dielectric layer may be made of a material that is harder than that of the second inorganic dielectric layer, which includes, but not limited to, one of silicon nitride and silicon oxynitride.

In one example, a material of the first inorganic dielectric layer is silicon nitride, and a material of the second inorganic dielectric layer is silicon oxide, which will reduce damage to the first inorganic dielectric layer caused by etching and reduce the difficulty of manufacturing the rewiring layer.

Specifically, the steps to form the rewiring layer 20 also include: using a process including but not limited to vapor deposition to form the first inorganic dielectric layer 202 over the metal wiring layer 201, and then using photolithography etching to form patterned areas or vias in the first inorganic dielectric layer 202. After that, using one or more of sputtering, electroplating, and chemical plating to form a metal material layer on the patterned areas or vias and on the first inorganic dielectric layer 202 to form another metal wiring layer 201; that is, the steps of forming a first patterned inorganic dielectric layer 202 and forming a metal wiring layer 201 may be performed more than once. Interconnection between different metal wiring layers is achieved by patterning the several inorganic dielectric layers or forming vias in the several inorganic dielectric layers; it should be noted that the number of the metal wiring layers and the inorganic dielectric layers can be adjusted to achieve different wiring functions, as long as the metal wiring layers are electrically connected to each other (when there are two or more metal wiring layers); the rewiring layer having an inorganic wiring layer reduces the residual stresses due to mechanical stresses and mismatch of thermal expansion coefficients between the chips and the rewiring layer.

In an example as shown in the figures, the rewiring layer 20 includes two or more first inorganic dielectric layers and two or more metal wiring layers, and the upper one of the first inorganic dielectric layers 202 is arranged to have vias 204 partially revealing a metal wiring layer beneath.

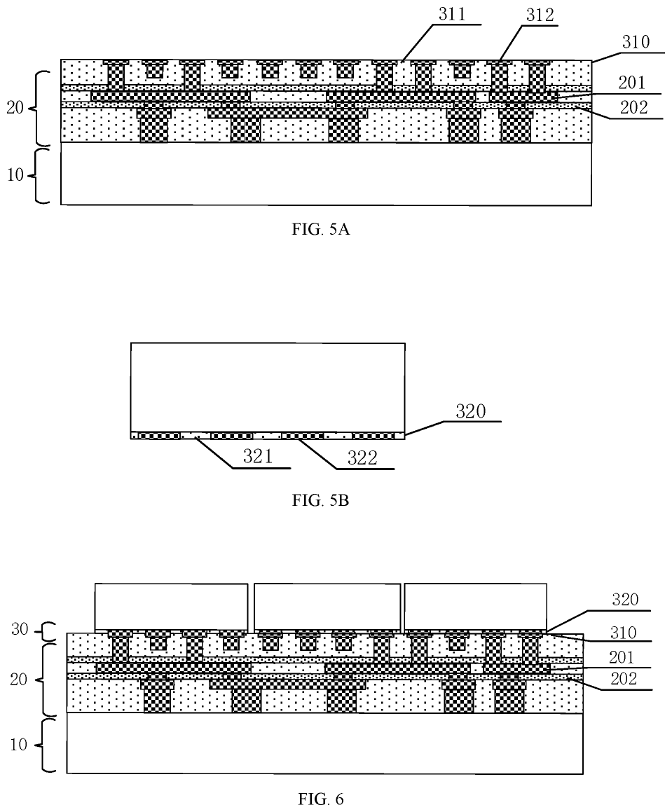

Referring to FIGS. 5A, 5B and 6, step S2 includes: forming the hybrid bonding structure 30 between the first surface of the rewiring layer 20 and the semiconductor chips.

As an example, step S2 includes: S2-1, forming a first bonding layer 310 on the first surface of the rewiring layer 20; and S2-2, aligning and directly bonding first pads 312 to second pads 322 on the semiconductor chip.

Specifically, as shown in FIGS. 5A to 5B, step S2-1 includes: forming a first passivation layer 311 on the first surface of the rewiring layer 20; forming openings in the first passivation layer 311 by a photolithography process and an etching process, and filling metal in the openings to form the first pads 312 in the first passivation layer 311. The first bonding layer 310 includes the first pads 312 in the patterned first passivation layer 311.

As an example, metal is disposed on the patterned first passivation layer 311 using sputtering, electroplating, chemical plating or other suitable processes to form the first pads 312; meanwhile the metal enters the vias 204 in the first inorganic dielectric layer 202 to form conductive plugs, thereby achieving electrical connection between the first bonding layer 310 and the rewiring layer 20. As shown in FIG. 5A, the first passivation layer 311 is formed on the uppermost one of the first inorganic dielectric layers 202; the openings in the first passivation layer 311 are formed by a photolithography process and an etching process, thereby obtaining a patterned first passivation layer, and revealing the vias 204 in said first inorganic dielectric layer; the patterned first passivation layer is filled with metal to form the first pads 312 embedded in the patterned first passivation layer. By defining the size and location of the first pads on the first passivation layer by a photolithographic process, the pitch between pins can be adjusted and the density of the I/O ports can be increased.

In one example, the first passivation layer 312 is made of the same material as the second inorganic dielectric layer, while in other examples, the first passivation layer 312 is made of a different material than the second inorganic dielectric layer. In one example, the first passivation layer may be made of one of silicon oxide and silicon nitride. Accordingly, as shown in FIG. 5B, a surface of the semiconductor chip is provided with a second bonding layer 320, and the second bonding layer 320 includes a second passivation layer 321 and second pads 322 in the second passivation layer.

Specifically, as shown in FIG. 6, steps S2-2 include: aligning and directly bonding the first pads 312 to the second pads 322 at one side of the semiconductor chips. In one example, the first passivation layer and the second passivation layer are hydrophilically bonded, while the first pads 312 are aligned with and directly bonded to the second pads 322, thereby forming a hybrid bonding structure between the semiconductor chips and the first rewiring layer, using no solder, and avoiding cracks caused by solder at the interface between the two. Preferably, the first pads 312 and the second pads 322 are made of copper, resulting in Cu—Cu bonded interconnections with better electrical conductivity and better resistance to electromigration.

Referring to FIG. 7, step S3 includes: forming a first plastic layer 410 on the first surface of the rewiring layer 20 to form the packaging layer 40, wherein the first plastic layer 410 covers the semiconductor chips.

As an example, the semiconductor chips may be functional chips, which include active devices as well as passive devices, achieving heterogeneous integration of active and passive devices, thereby forming a package that implements a specific function.

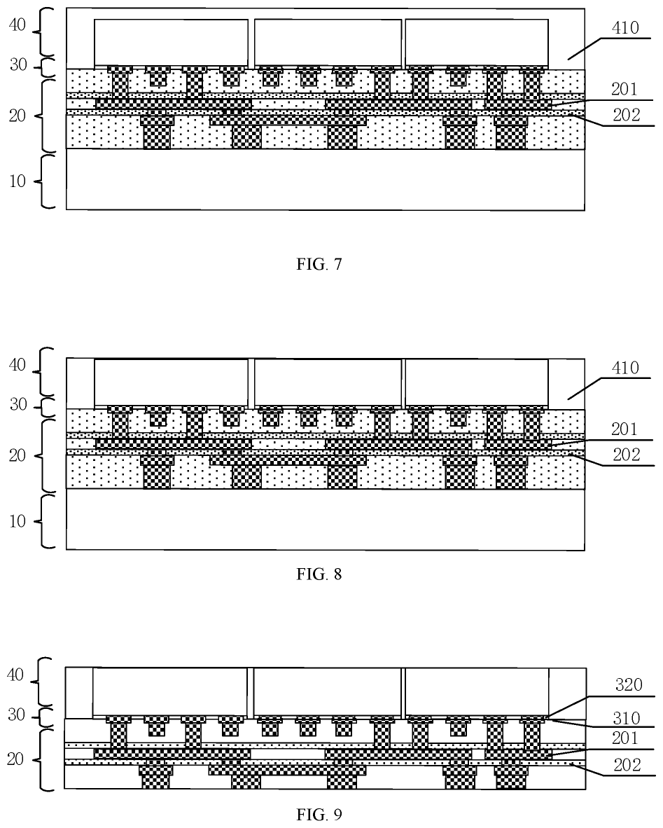

As an example, techniques of forming the first plastic layer includes, but is not limited to, one of compression molding, transfer molding, liquid seal molding, vacuum lamination, and spin coating; and the first plastic layer may be made of a curable material, such as a polymer-based material, a resin-based material, an epoxy resin, a liquid thermosetting epoxy resin, a plastic compound, a polyamide, and any combination thereof. Referring to FIG. 8, after forming the first plastic layer 410, a step of thinning the first plastic layer 410 may also be performed, and may include, for example, using a chemical mechanical polishing (CMP) process to flatten the first plastic layer 410 and reduce the thickness of the entire packaging structure.

Referring to FIG. 9, step S4 includes: removing the supporting substrate 10 to expose the second surface of the rewiring layer 20.

Specifically, the step of removing the supporting substrate 10 includes: performing a CMP process or etching on the supporting substrate 10. By removing the supporting substrate 10, the contact pads 212 and the patterned second inorganic dielectric layer 211 are revealed; the supporting substrate 10 is a silicon-based substrate.

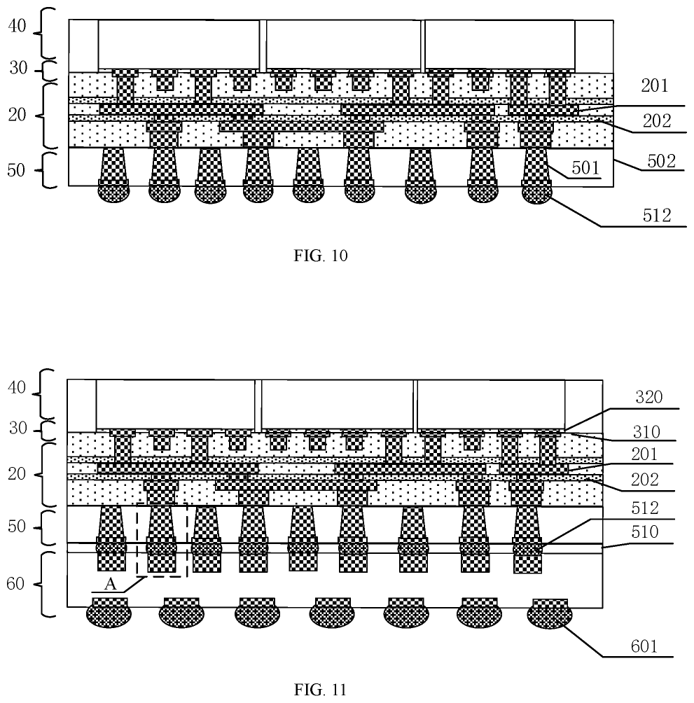

Referring to FIGS. 10 to 11, step S5 includes: providing a packaging substrate 60 electrically coupled to the second surface of the rewiring layer 20, including forming a conductive interconnection A between the second surface of the rewiring layer 20 and the packaging substrate 60, as indicated by the dotted box shown in FIG. 11.

Specifically, step S5 includes: S5-S1, forming a controlled collapse chip connection (C4) layer 50 on the second surface of the rewiring layer 20, wherein the C4 layer 50 includes conductive posts 501 and C4 bumps 512, wherein the C4 bumps 512 are located on a side of the C4 layer 50 facing away from the rewiring layer 20 and connected to the conductive posts 501; S5-2, aligning and bonding the C4 bumps 512 to contact pads provided on the packaging substrate 60.

As an example, at step S5-1, first ends of the conductive posts 501 are electrically connected to the second surface of the rewiring layer 20 and second ends of the conductive posts 501 are respectively electrically connected to the C4 bumps 512, wherein the conductive posts 501 are formed on the second surface of the rewiring layer using a wire bonding process, a deposition process, or other suitable process, and electrically connected to the contact pads 212 that are exposed on the second surface of the rewiring layer. As an example, the conductive posts 501 may be copper posts, titanium posts, or other conductive posts.

As an example, step S5-1 further includes: after forming the C4 bumps 512, filling bottom filler 502 around the conductive posts 501, wherein the bottom filler 502 contains a curable adhesive, the adhesive can fill gaps between the conductive posts 501, and then be cured to form the final bottom filler, protecting the conductive posts, and reducing stress of conductive interconnections.

As an example, step S5-2 further includes: electrically connecting the second surface of the rewiring layer 20 to the packaging substrate 60 by aligning and bonding the C4 bumps 512 to the contact pads provided on the packaging substrate 60, and forming a second plastic layer 510 at the gaps between the C4 layer 50 and the packaging substrate 60.

Referring to FIG. 11, the present disclosure also provides a system-level fan-out packaging structure, including: a rewiring layer 20, a hybrid bonding structure 30, and a packaging substrate 60, wherein the rewiring layer 20 has opposing first and second surfaces, the hybrid bonding structure 30 is located on the first surface of the rewiring layer 20 and is provided to electrically couple semiconductor chips to the first surface of the rewiring layer 20 so that the semiconductor chips are interconnected through the rewiring layer 20; the semiconductor chips are covered with a first plastic layer 410 to form a packaging layer 40; a conductive interconnection is formed between the packaging substrate 60 and the second surface of the rewiring layer 20 for electrical lead-out of the semiconductor chips and the rewiring layer 20.

As an example, the rewiring layer 20 includes one or more inorganic dielectric layers and at one or more metal wiring layers; the inorganic dielectric layers may include at least one first inorganic dielectric layer 202 and one second inorganic dielectric layer 210, with the first inorganic dielectric layer 202 formed after and over the second inorganic dielectric layer 210. The inorganic dielectric layers and the metal wiring layers are alternately formed and arranged along the vertical direction. Here, the rewiring layer 20 uses inorganic dielectric materials as insulating materials, and is configured as an inorganic-material-based wiring layer, which can reduce the line spacing within the rewiring layer 20 to less than 1 μm, minimize the package volume, replace TSV adapters, and reduce the manufacturing cost.

As an example, a material of the first inorganic dielectric layer is different from a material of the second inorganic dielectric layer and includes, but is not limited to, one of silicon nitride and silicon nitride oxide; for example, the first inorganic dielectric layer includes silicon nitride and the second inorganic dielectric layer includes silicon oxide.

As an example, materials of the metal wiring layer include one or more of copper, aluminum, nickel, gold, silver, and titanium.

As an example, a first bonding layer 310 is formed on the first surface of the rewiring layer 20, and a second bonding layer 320 is formed on the semiconductor chips, wherein the hybrid bonding structure 30 includes the first bonding layer 310, and the second bonding layer 310, wherein the first bonding layer 310 and the second bonding layer 320 are directly bonded, and a bonding interface therebetween has an interconnection pitch of less than 10 microns.

As an example, the conductive interconnection includes a C4 layer 50 provided on the second surface of the rewiring layer 20, wherein the C4 layer 50 includes conductive posts 501 and a bottom filler layer 502 encasing the conductive posts 501, wherein the conductive posts 501 include one of copper posts and titanium posts.

As an example, the conductive interconnection also includes C4 bumps 512 disposed on a first surface of the packaging substrate 60, the C4 bumps 512 are located on a side of the C4 layer 50 facing away from the rewiring layer 20 and connected to the conductive posts 501, a second plastic layer 510 is formed at gaps between the C4 layer 50 and the packaging substrate 60, thereby electrically coupling the second surface of the rewiring layer 20 to the packaging substrate 60 through the C4 layer 50.

As an example, metal bumps 601 are disposed on a second surface of the packaging substrate 60 to enable connection of the package body with external chips or packaging units.

In some examples, the semiconductor chips may be functional chips, which include active devices, such as logic devices, high bandwidth memory devices, switches, power management units, and surface mounted devices; and passive devices, such as resistors, inductors, capacitors, etc.

As shown in FIG. 11, the system-level fan-out packaging structure can be a system-in-package module (SIP Module) that can integrate a processor, sensor, data encryption chip, actuator, memory, connector, and security chip. These active and passive devices are arranged side by side and are electrically connected to the rewiring layer 20 by the hybrid bonding structure 30, wherein two or more heterogeneous semiconductor components and passive devices are integrated into a standard package to achieve substantially complete functionality using the hybrid bonding structure 30, thereby allowing more flexibility in customizing the packaging structure for desired functions.

In summary, in the system-level fan-out packaging structure of the present disclosure, the hybrid bonding structure is used to bond the rewiring layer to the semiconductor chips without solder, avoiding cracks in the solder at the interface between the two and improving the reliability of interconnection, while increasing the functional integration of the fan-out packaging structure, providing more flexible chip heterogeneous integration solutions, and realizing a high-performance system-level fan-out packaging structure.

The system-level fan-out packaging structure of the present disclosure does not require the use of TSV adapters, realizes heterogeneous integration and interconnection of multiple chips, and reduces the cost of package manufacturing, and the interconnection pitch is less than 10 microns, which is conducive to reducing pin pitch, and thus can increase the density of I/O ports.

In the method for manufacturing the system-level fan-out packaging structure of the present disclosure, by using inorganic dielectric materials for insulating the rewiring layer, the line spacing within the rewiring layer is reduced to less than 1 μm, and hybrid bonding is achieved at the interface between the rewiring layer and the semiconductor chips. This avoids forming interfaces between organic and inorganic materials, improves process integration in packaging manufacturing, and minimizes package volume. Therefore, the present disclosure effectively overcomes various shortcomings in the existing technology and has high industrial utilization value.

The above-mentioned embodiments are just used for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A method for manufacturing a system-level fan-out packaging structure, comprising:
forming a rewiring layer on a supporting substrate, wherein the rewiring layer includes a first surface and a second surface opposite to the first surface, at least one inorganic dielectric layer, and at least one metal wiring layer;
forming a hybrid bonding structure between the first surface of the rewiring layer and semiconductor chips to electrically couple the semiconductor chips to the first surface of the rewiring layer, wherein the hybrid bonding structure comprises a first bonding layer formed on the first surface of the rewiring layer;
forming a plastic layer on the first surface of the rewiring layer to form a packaging layer cover the semiconductor chips;
removing the supporting substrate to expose the second surface of the rewiring layer; and
providing a packaging substrate electrically coupled to the second surface of the rewiring layer, wherein a conductive interconnection piece is arranged to be between the second surface of the rewiring layer and the packaging substrate.

2. The method for manufacturing the system-level fan-out packaging structure according to claim 1, wherein the rewiring layer includes two or more inorganic dielectric layers and two or more metal wiring layers, wherein the two or more inorganic dielectric layers are alternately formed with the two or more metal wiring layers in a direction perpendicular to the supporting substrate.

3. The method for manufacturing the system-level fan-out packaging structure according to claim 1, wherein removing the supporting substrate includes: thinning the supporting substrate using a mechanical grinding process, then removing the thinned supporting substrate using a chemical-mechanical polishing process, wherein the supporting substrate is a silicon-based substrate.

4. The method for manufacturing the system-level fan-out packaging structure according to claim 1, wherein the first bonding layer is formed on the first surface of the rewiring layer by a process of:
forming a first passivation layer on the first surface of the rewiring layer; and
forming vias in the first passivation layer by a photolithography process and an etching process; and filling the vias with a metal to form first pads.

5. The method for manufacturing the system-level fan-out packaging structure according to claim 1, wherein a material of the at least one inorganic dielectric layer includes one of silicon nitride and silicon oxynitride, and a material of the at least one metal wiring layer includes one or more of copper, aluminum, nickel, gold, silver, and titanium.

6. The method for manufacturing the system-level fan-out packaging structure according to claim 1, wherein forming the conductive interconnection further comprising:
forming a controlled-collapse-chip-connection (C4) layer on the second surface of the rewiring layer, wherein the C4 layer comprises conductive posts and C4 bumps; and
aligning and bonding the C4 bumps to contact pads provided on the packaging substrate.

7. A system-level fan-out packaging structure, comprising:
a rewiring layer having a first surface and a second surface opposite to the first surface, wherein a first bonding layer is provided on the first surface of the rewiring layer, and wherein the rewiring layer comprises at least one inorganic dielectric layer and at least one metal wiring layer vertically stacked;
a hybrid bonding structure, disposed on the first surface of the rewiring layer and electrically coupling semiconductor chips to the first surface of the rewiring layer for interconnection among the semiconductor chips through the rewiring layer, wherein the semiconductor chips are covered by a first plastic layer to form a packaging layer; and
a packaging substrate, wherein a conductive interconnection is formed between the packaging substrate and the second surface of the rewiring layer, wherein the packaging substrate achieves electrical lead-out of the semiconductor chips and the rewiring layer.

8. The system-level fan-out packaging structure according to claim 8, wherein the conductive interconnection includes a C4 layer provided on the second surface of the rewiring layer, wherein the C4 layer includes conductive posts and a bottom filler layer encasing the conductive posts, wherein the conductive posts include one of copper posts and titanium posts.

9. The system-level fan-out packaging structure according to claim 8, wherein the conductive interconnection further includes C4 bumps provided on a side of the C4 layer facing away from the rewiring layer and connected to the conductive posts.

10. The system-level fan-out packaging structure according to claim 7, wherein the semiconductor chips include an active device and a passive device arranged side by side.

11. The system-level fan-out packaging structure according to claim 7, wherein the hybrid bonding structure comprises the first bonding layer and a second bonding layer provided on surfaces of the semiconductor chips, wherein the first bonding layer and the second bonding layer are directly bonded, and a bonding interface therebetween has an interconnection pitch of less than 10 microns.
